(19) United States
(12) Patent Application Publication
(10) Pub. No.: US 2026/0212944 A1
(43) Pub. Date: Jul. 23, 2026

(54) MEMORY SYSTEM FOR DETECTING FAULT IN SIGNAL TRANSMISSION PATH

(71) Applicant: SK hynix Inc., Icheon-si Gyeonggi-do (KR)

(72) Inventors: Chang Kwon LEE, Icheon-si Gyeonggi-do (KR); Haeng Seon CHAE, Icheon-si Gyeonggi-do (KR); Hong Seok CHOI, Icheon-si Gyeonggi-do (KR)

(73) Assignee: SK hynix Inc., Icheon-si Gyeonggi-do (KR)

(21) Appl. No.: 19/204,161

(22) Filed: May 9, 2025

(30) Foreign Application Priority Data
Jan. 17, 2025 (KR) 10-2025-0007593

(51) Int. Cl. G11C 29/18; H01L 25/065; H01L 25/18; H10B 80/00

(52) U.S. Cl. CPC G11C 29/18; H10B 80/00; H10W 90/00; H10W 90/297; H10W 90/722; H10W 90/724

(57) ABSTRACT

A memory system includes a base die configured to control operations of a plurality of core dies. The base die applies a command address to a command address through silicon via (TSV) by receiving the command address through a first signal transmission path after the start of a wafer test operation, outputs a latch command address generated based on a logic level of the command address TSV as data through a second signal transmission path after the start of a read operation, and detects a fault in the first signal transmission path based on a logic level of the data.

### CROSS-REFERENCE TO RELATED APPLICATION

The present application claims priority under 35 U.S.C. § 119(a) to Korean Patent Application No. 10-2025-0007593, filed in the Korean Intellectual Property Office on Jan. 17, 2025, which application is incorporated herein by reference in its entirety.

### BACKGROUND

The present disclosure relates to a memory system for detecting a fault in a signal transmission path.

Recently, a stack memory system, such as high bandwidth memory (HBM), is used in wide application fields due to its excellent bandwidth. Unlike the existing memory system using a parallel data bus, the stack memory system includes a stack memory device including a base die and core dies that are connected by through silicon vias (TSVs). The stack memory device includes a physical interface, such as a physical layer, for communication with a processor.

### SUMMARY

In an embodiment, a memory system may include a base die configured to control operations of a plurality of core dies and a processor connected to the base die. The base die applies a command address to a command address through silicon via (TSV) by receiving the command address through a first signal transmission path after the start of a wafer test operation, outputs a latch command address generated based on a logic level of the command address TSV as data through a second signal transmission path after the start of a read operation, and detects a fault in the first signal transmission path based on a logic level of the data.

In an embodiment, a memory system may include a base die configured to control operations of a plurality of core dies and a processor connected to the base die. The base die applies a command address to a command address through silicon via (TSV) by receiving the command address through a first signal transmission path after the start of a wafer test operation, outputs a latch command address generated based on a logic level of the command address TSV as data through a second signal transmission path, applies the data to a data TSV by receiving the data through the second signal transmission path, outputs transfer data generated based on a logic level of the data TSV as the data through the second signal transmission path, and detects a fault in the first signal transmission path and the second signal transmission path based on a logic level of the data.

In an embodiment, a memory system may include a base die configured to control operations of a plurality of core dies and a processor connected to the base die. The base die sequentially applies a command address to a plurality of command address through silicon vias (TSVs) by receiving the command address through a plurality of first signal transmission paths after the start of a wafer test operation, sequentially outputs a plurality of latch command addresses generated based on logic levels of the plurality of command address TSVs as data through a second signal transmission path after the start of a read operation, and detects a fault in the plurality of first signal transmission paths based on a logic level of the data.

In an embodiment, a base die may include a data (DA) pad region configured to receive a command address and configured to input and output data, a physical region configured to generate an internal command address by receiving the command address, a through silicon via (TSV) region configured to apply the internal command address to a command address TSV and configured to generate a latch command address based on a logic level of the command address TSV, and a data input and output circuit configured to generate the data based on the latch command address after the start of a read operation of a wafer test operation and configured to output the data to the DA pad region. The base die detects a fault in the physical region and the TSV region based on a logic level of the data.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a base die according to an embodiment of the present disclosure.

FIG. 3 is a diagram illustrating a construction of a command address physical region according to an embodiment of the present disclosure.

FIG. 4 is a diagram illustrating a construction of a data physical region according to an embodiment of the present disclosure.

FIG. 5 is a diagram illustrating a construction according to an embodiment of a command address TSV region according to another embodiment of the present disclosure.

FIG. 6 is a diagram illustrating a construction according to an embodiment of a data TSV region according to another embodiment of the present disclosure.

FIG. 7 is a block diagram illustrating a construction according to an embodiment of a data input and output circuit according to an embodiment of the present disclosure.

FIG. 8 is a table for describing a command address that performs a read operation according to an embodiment of the present disclosure.

FIG. 9 is a block diagram illustrating a construction of a data processing circuit according to an embodiment of the present disclosure.

FIG. 10 is a block diagram illustrating a construction of a read processing circuit according to an embodiment of the present disclosure.

FIG. 11 is a block diagram illustrating a construction of a pipe circuit according to an embodiment of the present disclosure.

FIG. 12 is a diagram for describing an operation of detecting a fault in a signal transmission path along which the command address is transmitted after the start of a wafer test operation in the base die according to an embodiment of the present disclosure.

FIGS. 13 and 14 are timing diagrams for describing a wafer test operation in the base die according to an embodiment of the present disclosure.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “binary bit set” may mean a combination of logic levels of bits included in a signal. When a logic level of each of the bits included in the signal is changed, a binary bit set of the signal may be differently set. For example, when the logic level of each of two bits included in a signal is a “logic low level, a logic low level” when the two bits are included in the signal, a binary bit set of the signal may be set as “00.” When the logic level of each of the two bits included in the signal is a “logic low level, logic high level”, a binary bit set of the signal may be set as “01.”

Hereafter, the present disclosure will be described in more detail through embodiments. The embodiments are only used to exemplify the present disclosure, and the scope of the present disclosure is not limited by the embodiments.

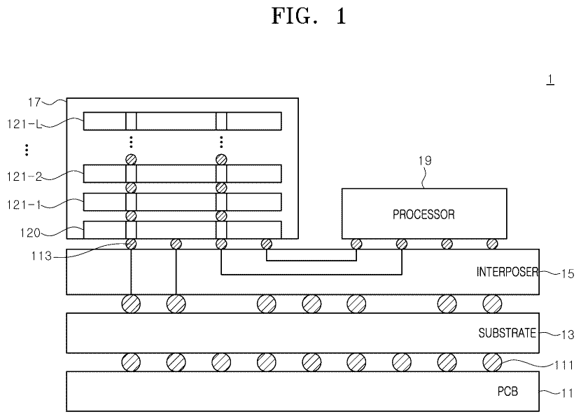

FIG. 1 is a block diagram illustrating a construction of a memory system 1 according to an embodiment of the present disclosure.

As illustrated in FIG. 1, the memory system 1 may include a printed circuit board (PCB) 11, a substrate 13, an interposer 15, a memory device 17, and a processor 19.

The PCB 11 may connect several electronic parts in order to form an electronic circuit (not illustrated). A copper layer, a solder mask, and a silk screen may be formed on the PCB 11. A circuit path that transmits a signal or power may be formed in the copper layer. The solder mask may prevent damage to the circuit and protects a specific region in which a part may be soldered. Furthermore, the silk screen may indicate a position or information of an electronic part in the form of characters or symbols printed on a surface of the PCB 11.

The substrate 13 may be formed over the PCB 11 through bump pads (e.g., 111), and may mechanically support the interposer 15, the memory device 17, and the processor 19. The substrate 13 may be used as an insulator as a material, that is, a physical base for the PCB 11, in general. The material of the substrate 13 may include FR4, that is, an insulator made of glass fiber and epoxy resin, ceramics that can withstand a high temperature and is commonly used in a high frequency circuit or a high temperature environment due to its thermal conductivity, and polyimide that is used as a base material for a flexible PCB due to its flexible characteristic.

The interposer 15 may be formed over the substrate 13 through bump pads and may include wires that connect electronic parts (e.g., the memory device 17 and the processor 19), the form factors or pin arrangements of which do not match with the substrate 13. The interposer 15 may convert signals in different interfaces.

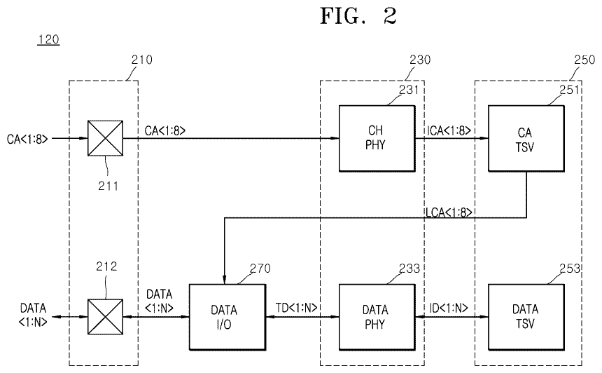

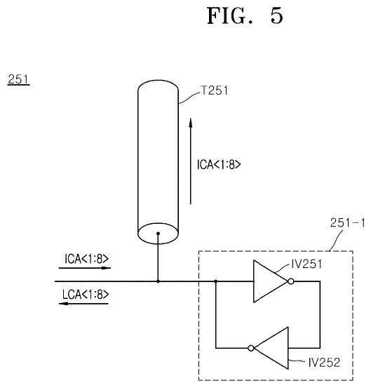

The memory device 17 may be formed over the interposer 15 through micro bump pads (e.g., 113). The memory device 17 may store data applied by the processor 19 or may output data stored in the memory device 17 to the processor 19, under the control of the processor 19. The memory device 17 may include a base die 120 and a plurality of core dies 121-1 to 121-L. The plurality of core dies 121-1 to 121-L may be stacked over the base die 120 through micro bump pads. The base die 120 and the plurality of core dies 121-1 to 121-L may be vertically connected through TSVs. The base die 120 and the plurality of core dies 121-1 to 121-L may be vertically stacked over the base die 120 through the TSVs after a wafer test operation is performed. The base die 120 may receive a command address (CA<1:8> in FIG. 2) through a first signal transmission path after the start of a wafer test operation and may apply the command address to a command address TSV (T251 in FIG. 5). The base die 120 may output a latch command address (LCA<1:8> in FIG. 2) generated based on the logic level of the command address TSV (T251 in FIG. 5) as data (DATA<1:N> in FIG. 2) through a second signal transmission path after the start of a read operation of a wafer test operation. The base die 120 may detect a fault in the first signal transmission path based on the logic level of the data (DATA<1:N> in FIG. 2) after the start of a read operation of a wafer test operation. The base die 120 may control data to be efficiently transmitted between the processor 19 and the plurality of core dies 121-1 to 121-L. The wafer test operation may be set as a test operation that is performed in a wafer state before the base die 120 and the plurality of core dies 121-1 to 121-L are vertically stacked. An operation after the wafer test operation is performed may mean an operation after the plurality of core dies 121-1 to 121-L is vertically stacked on the base die 120. The first signal transmission path may be set as a signal transmission path along which the command address (CA<1:8> in FIG. 2) is applied. The second signal transmission path may be set as a signal transmission path along which the data (DATA<1:N> in FIG. 2) are input and output. The base die 120 may be configured as a base chip or a semiconductor chip. The core dies 121-1 to 121-L may each be configured as a core chip or a semiconductor chip.

Each of the plurality of core dies 121-1 to 121-L may include a plurality of channel regions that independently operates. Each of the plurality of channel regions may be assigned a channel that independently operates and may receive or transmit data. Each of the plurality of channel regions may be implemented to include a core region and may receive or transmit data. The number “L” of core dies 121-1 to 121-L may be 4, 8, 12, or 16. For example, when each of the core dies 121-1 to 121-12 has 8 channels, each of the core dies 121-1 to 121-4, the core dies 121-5 to 121-8, and the core dies 121-9 to 121-12 may transmit and receive data to and from the processor 19 in a rank unit in which each of the core dies 121-1 to 121-4, the core dies 121-5 to 121-8, and the core dies 121-9 to 121-12 consists of 32 channels including 32 channel regions.

The processor 19 may control the base die 120 to output the command address (CA<1:8> in FIG. 2), through a wire formed within the interposer 15, to the core dies 121-1 to 121-L except for a signal transmission path having a fault, among the signal transmission paths of the base die 120.

FIG. 2 is a block diagram illustrating a construction of the base die 120 according to an embodiment of the present disclosure.

As illustrated in FIG. 2, the base die 120 may include a data (DA) pad region 210, a physical region 230, a TSV region 250, and a data input and output circuit (DA I/O) 270.

The DA pad region 210 may include a first pad 211 and a second pad 212.

The first pad 211 may be set as a pad that receives the command address CA<1:8>. The first pad 211 may receive and output the command address CA<1:8> after the start of a wafer test operation. The first pad 211 may output the command address CA<1:8> to a command address physical region (CH PHY) 231. The command address CA<1:8> may include 8 bits but may be set to include various bits according to an embodiment.

The second pad 212 may be set as a pad that inputs and outputs the data DATA<1:N>. The second pad 212 may receive and output the data DATA<1:N> after the start of a wafer test operation. The second pad 212 may receive the data DATA<1:N> from the processor 19 and may output the data DATA<1:N> to the data input and output circuit 270. The second pad 212 may receive the data DATA<1:N> from the data input and output circuit 270 and may output the data DATA<1:N> to the processor 19. The number “N” of bits of the data DATA<1:N> may be set as an integer greater than 0.

The DA pad region 210 may receive the command address CA<1:8> from the processor 19 through a wire of the interposer 15 after the start of a wafer test operation. The DA pad region 210 may receive the data DATA<1:N> from the processor 19 through a wire of the interposer 15 or may output the data DATA<1:N> to the processor 19 through a wire of the interposer 15, after the start of a wafer test operation. The DA pad region 210 is shown to include only the first pad 211 and the second pad 212; however, the DA pad region may be implemented to include multiple pads.

The DA pad region 210 may be set as a region including a plurality of pads that is connected to a probe pin of a test device that performs tests. The DA pad region 210 according to the present embodiment is implemented to be connected to the processor 19 through a wire of the interposer 15; however, the DA pad region may be implemented to be connected to an external test device that performs tests.

The physical region 230 may include the command address physical region 231 and a data physical region 233.

The command address physical region 231 may generate an internal command address ICA<1:8> by receiving the command address CA<1:8> after the start of a wafer test operation. The command address physical region 231 may generate the internal command address ICA<1:8> by receiving the command address CA<1:8> from the first pad 211. The command address physical region 231 may generate the internal command address ICA<1:8> by buffering the command address CA<1:8>. The command address physical region 231 may output the internal command address ICA<1:8> to a command address TSV region (CA TSV) 251. The command address physical region 231 may generate the internal command address ICA<1:8> by receiving the command address CA<1:8> after a wafer test operation. The command address physical region 231 may output the internal command address ICA<1:8> to the command address TSV region 251 after a wafer test operation.

The data physical region 233 may generate internal data ID<1:N> by receiving transfer data TD<1:N> after the start of a wafer test operation. The data physical region 233 may generate the internal data ID<1:N> by receiving the transfer data TD<1:N> from the data input and output circuit 270 after the start of a write operation of a wafer test operation. The data physical region 233 may generate the internal data ID<1:N> by buffering the transfer data TD<1:N> after the start of a write operation of a wafer test operation. The data physical region 233 may output the internal data ID<1:N> to a data TSV region (DATA TSV) 253 after the start of a write operation of a wafer test operation.

The data physical region 233 may generate the internal data ID<1:N> by receiving the transfer data TD<1:N> from the data input and output circuit 270 after the start of a write operation after a wafer test operation. The data physical region 233 may generate the internal data ID<1:N> by buffering the transfer data TD<1:N> after the start of a write operation after a wafer test operation. The data physical region 233 may output the internal data ID<1:N> to the data TSV region 253 after the start of a write operation after a wafer test operation. The number “N” of bits of each of the transfer data TD<1:N> and the internal data ID<1:N> may be set as an integer greater than 0.

The data physical region 233 may generate the transfer data TD<1:N> by receiving the internal data ID<1:N> after the start of a wafer test operation. The data physical region 233 may generate the transfer data TD<1:N> by receiving the internal data ID<1:N> from the data TSV region 253 after the start of a read operation of a wafer test operation. The data physical region 233 may generate the transfer data TD<1:N> by buffering the internal data ID<1:N> after the start of a read operation of a wafer test operation. The data physical region 233 may output the transfer data TD<1:N> to the data input and output circuit 270 after the start of a read operation of a wafer test operation.

The data physical region 233 may generate the transfer data TD<1:N> by receiving the internal data ID<1:N> from the data TSV region 253 after the start of a read operation after a wafer test operation. The data physical region 233 may generate the transfer data TD<1:N> by buffering the internal data ID<1:N> after the start of a read operation after a wafer test operation. The data physical region 233 may output the transfer data TD<1:N> to the data input and output circuit 270 after the start of a read operation after a wafer test operation.

The command address physical region 231 and the data physical region 233 may each include a physical interface, such as a physical layer. The physical layer may be designed to guarantee high speed data transfer and efficient communication.

The TSV region 250 may include the command address TSV region 251 and the data TSV region 253.

The command address TSV region 251 may receive the internal command address ICA<1:8> after the start of a wafer test operation. The command address TSV region 251 may apply the internal command address ICA<1:8> to the command address TSV (T251 in FIG. 5) after the start of a wafer test operation. The command address TSV region 251 may latch the internal command address ICA<1:8> after the start of a wafer test operation. The command address TSV region 251 may generate the latch command address LCA<1:8> based on the logic level of the command address TSV (T251 in FIG. 5) after the start of a wafer test operation. The command address TSV region 251 may output the latch command address LCA<1:8> to the data input and output circuit 270 after the start of a wafer test operation.

The command address TSV region 251 may receive the internal command address ICA<1:8> after a wafer test operation. The command address TSV region 251 may apply the internal command address ICA<1:8> to the command address TSV (T251 in FIG. 5) after a wafer test operation. The command address TSV region 251 may output the internal command address ICA<1:8> to the plurality of core dies 121-1 to 121-L through the command address TSV (T251 in FIG. 5) after a wafer test operation.

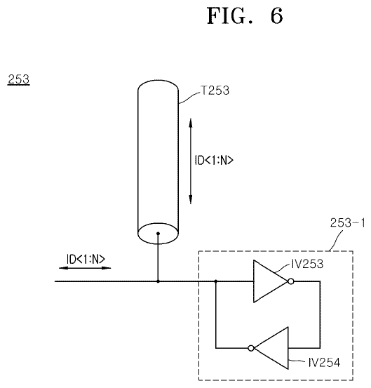

The data TSV region 253 may receive the internal data ID<1:N> after the start of a write operation of a wafer test operation. The data TSV region 253 may apply the internal data ID<1:N> to a data TSV (T253 in FIG. 6) after the start of a write operation of a wafer test operation. The data TSV region 253 may latch the internal data ID<1:N> after the start of a write operation of a wafer test operation.

The data TSV region 253 may output the internal data ID<1:N> that are latched after the start of a read operation of a wafer test operation. The data TSV region 253 may output the internal data ID<1:N> to the data physical region 233 after the start of a read operation of a wafer test operation.

The data TSV region 253 may receive the internal data ID<1:N> after the start of a write operation after a wafer test operation. The data TSV region 253 may apply the internal data ID<1:N> to the data TSV (T253 in FIG. 6) after the start of a write operation after a wafer test operation. The data TSV region 253 may output the internal data ID<1:N> to the plurality of core dies 121-1 to 121-L through the data TSV (T253 in FIG. 6) after the start of a write operation after a wafer test operation.

The data TSV region 253 may receive the internal data ID<1:N> from the plurality of core dies 121-1 to 121-L after the start of a read operation after a wafer test operation. The data TSV region 253 may output the internal data ID<1:N> to the data physical region 233 after the start of a read operation after a wafer test operation.

The data input and output circuit 270 may generate the transfer data TD<1:N> based on the data DATA<1:N> after the start of a write operation of a wafer test operation. The data input and output circuit 270 may output the transfer data TD<1:N> to the data physical region 233 after the start of a write operation of a wafer test operation.

The data input and output circuit 270 may generate the data DATA<1:8> based on the latch command address LCA<1:8> after the start of a read operation of a wafer test operation. The data input and output circuit 270 may output the data DATA<1:8> to the second pad 212 after the start of a read operation of a wafer test operation.

The data input and output circuit 270 may generate the transfer data TD<1:N> based on the data DATA<1:N> after the start of a write operation after a wafer test operation. The data input and output circuit 270 may output the transfer data TD<1:N> to the data physical region 233 after the start of a write operation after a wafer test operation.

The data input and output circuit 270 may generate the data DATA<1:N> based on the transfer data TD<1:N> after the start of a read operation after a wafer test operation. The data input and output circuit 270 may output the data DATA<1:N> to the second pad 212 after the start of a read operation after a wafer test operation.

The first signal transmission path may be set as a path including the command address physical region 231 and the command address TSV region 251. The first signal transmission path may be set as a unilateral signal transmission path that receives the command address CA<1:8>.

The second signal transmission path may be set as a path including the data physical region 233, the data TSV region 253, and the data input and output circuit 270. The second signal transmission path may be set as a bidirectional signal transmission path that receives and transmits the data DATA<1:N>.

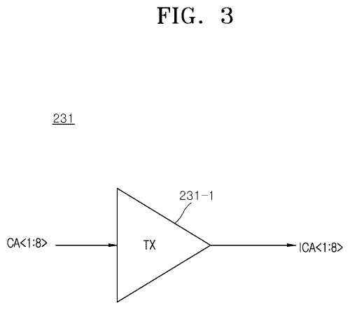

FIG. 3 is a diagram illustrating a construction of the command address physical region 231 according to an embodiment of the present disclosure.

As illustrated in FIG. 3, the command address physical region 231 may be implemented with a transmitter (TX) 231-1.

The transmitter 231-1 may generate the internal command address ICA<1:8> by receiving the command address CA<1:8> after the start of a wafer test operation. The transmitter 231-1 may generate the internal command address ICA<1:8> by buffering the command address CA<1:8> after the start of a wafer test operation. The transmitter 231-1 may output the internal command address ICA<1:8>to the command address TSV region 251 after the start of a wafer test operation.

The transmitter 231-1 may generate the internal command address ICA<1:8> by receiving the command address CA<1:8> after a wafer test operation. The transmitter 231-1 may generate the internal command address ICA<1:8> by buffering the command address CA<1:8> after a wafer test operation. The transmitter 231-1 may output the internal command address ICA<1:8> to the command address TSV region 251 after a wafer test operation.

FIG. 3 illustrates that the command address physical region 231 is implemented with one transmitter 231-1, for convenience of description. However, the command address physical region may be implemented with a plurality of transmitters that transmits the internal command address ICA<1:8>.

The command address physical region 231 is implemented with the transmitter 231-1 and may be set as a unilateral signal transmission path.

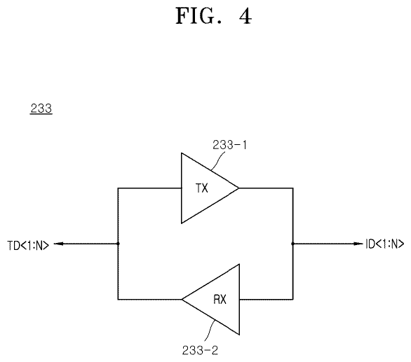

FIG. 4 is a diagram illustrating a construction of the data physical region 233 according to an embodiment of the present disclosure.

As illustrated in FIG. 4, the data physical region 233 may be implemented with a transmitter (TX) 233-1 and a receiver (RX) 233-2.

The transmitter 233-1 may generate the internal data ID<1:N> by receiving the transfer data TD<1:N> after the start of a write operation of a wafer test operation. The transmitter 233-1 may generate the internal data ID<1:N> by buffering the transfer data TD<1:N> after the start of a write operation of a wafer test operation. The transmitter 233-1 may output the internal data ID<1:N> to the data TSV region 253 after the start of a write operation of a wafer test operation.

The transmitter 233-1 may generate the internal data ID<1:N> by receiving the transfer data TD<1:N> after the start of a write operation after a wafer test operation. The transmitter 233-1 may generate the internal data ID<1:N> by buffering the transfer data TD<1:N> after the start of a write operation after a wafer test operation. The transmitter 233-1 may output the internal data ID<1:N>to the data TSV region 253 after the start of a write operation after a wafer test operation.

The receiver 233-2 may generate the transfer data TD<1:N> by receiving the internal data ID<1:N> after the start of a read operation of a wafer test operation. The receiver 233-2 may generate the transfer data TD<1:N> by buffering the internal data ID<1:N> after the start of a read operation of a wafer test operation. The receiver 233-2 may output the transfer data TD<1:N> to the data input and output circuit 270 after the start of a read operation of a wafer test operation.

The receiver 233-2 may generate the transfer data TD<1:N> by receiving the internal data ID<1:N> after the start of a read operation after a wafer test operation. The receiver 233-2 may generate the transfer data TD<1:N> by buffering the internal data ID<1:N> after the start of a read operation after a wafer test operation. The receiver 233-2 may output the transfer data TD<1:N> to the data input and output circuit 270 after the start of a read operation after a wafer test operation.

FIG. 4 illustrates that the data physical region 233 is implemented with one transmitter 233-1 and one receiver 233-2, for convenience of description. However, the data physical region may be implemented with a plurality of transmitters and a plurality of receivers that transmit and receive the transfer data TD<1:N> and the internal data ID<1:N>.

The data physical region 233 is implemented with the transmitter 233-1 and the receiver 233-2 and may be set as a bidirectional signal transmission path.

FIG. 5 is a diagram illustrating a construction according to an embodiment of the command address TSV region 251 according to another embodiment of the present disclosure.

As illustrated in FIG. 5, the command address TSV region 251 may include the command address TSV T251 and a command address latch circuit 251-1.

The command address TSV T251 may transfer the internal command address ICA<1:8> after the start of a wafer test operation. The command address TSV T251 may transfer the internal command address ICA<1:8> to the plurality of core dies 121-1 to 121-L after a wafer test operation. The command address TSV T251 may be set as a unilateral signal transmission path that outputs the internal command address ICA<1:8> to the plurality of core dies 121-1 to 121-L.

The command address latch circuit 251-1 may be implemented with inverters IV251 and IV252. The command address latch circuit 251-1 may latch the internal command address ICA<1:8>after the start of a wafer test operation. The command address latch circuit 251-1 may generate the latch command address LCA<1:8>based on the logic level of the command address TSV T251 after the start of a wafer test operation. The command address latch circuit 251-1 may output the latch command address LCA<1:8> to the data input and output circuit 270 after the start of a wafer test operation.

Each of the command address TSV T251 and the command address latch circuit 251-1 is illustrated as one component, but a plurality of command address TSVs and a plurality of command address latch circuits that transmit the internal command address ICA<1:8> to the plurality of core dies 121-1 to 121-L may be implemented.

FIG. 6 is a diagram illustrating a construction according to an embodiment of the data TSV region 253 according to another embodiment of the present disclosure.

As illustrated in FIG. 6, the data TSV region 253 may include the data TSV T253 and a data latch circuit 253-1.

The data TSV T253 may receive the internal data ID<1:N>after the start of a wafer test operation. The data TSV T253 may transfer the internal data ID<1:N> to the plurality of core dies 121-1 to 121-L after the start of a write operation after a wafer test operation. The data TSV T253 may transfer the internal data ID<1:N> from the plurality of core dies 121-1 to 121-L to the data input and output circuit 270 of FIG. 2 after the start of a read operation after a wafer test operation.

The data TSV T253 may be set as a bidirectional signal transmission path that transfers the internal data ID<1:N> to and from the plurality of core dies 121-1 to 121-L.

The data latch circuit 253-1 may be implemented with inverters IV253 and IV254. The data latch circuit 253-1 may latch the internal data ID<1:N> after the start of a wafer test operation. The data latch circuit 253-1 may output, to the data input and output circuit 270, the internal data ID<1:N> that are latched after the start of a wafer test operation.

Each of the data TSV T253 and the data latch circuit 253-1 is illustrated as one component, but a plurality of data TSVs and a plurality of data latch circuits that transmit and receive the plurality of core dies 121-1 to 121-L and the internal data ID<1:N> may be implemented.

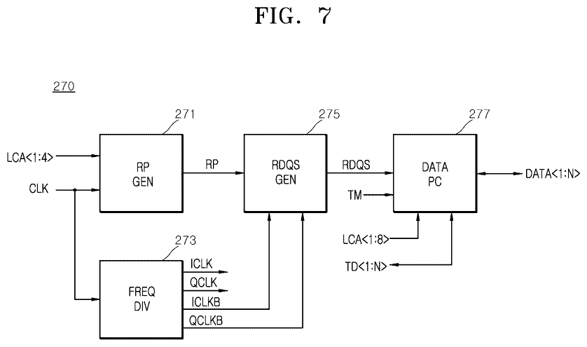

FIG. 7 is a block diagram illustrating a construction according to an embodiment of the data input and output circuit 270 according to an embodiment of the present disclosure.

As illustrated in FIG. 7, the data input and output circuit 270 may include a read pulse generation circuit (RP GEN) 271, a frequency division circuit (FREQ DIV) 273, a read strobe signal generation circuit (RDQS GEN) 275, and a data processing circuit (DATA PC) 277.

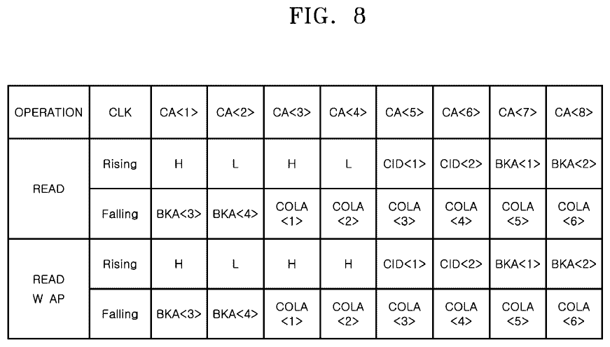

The read pulse generation circuit 271 may generate a read pulse RP based on the first to fourth bits LCA<1:4> of the latch command address in synchronization with a clock signal CLK. The read pulse generation circuit 271 may generate the read pulse RP when the first to fourth bits LCA<1:4> of the latch command address that is input in synchronization with the clock signal CLK have a logic level combination for performing a read operation. The first to fourth bits LCA<1:4> of the latch command address for generating the read pulse RP are described in detail with reference to FIG. 8.

The frequency division circuit 273 may generate a first internal clock signal ICLK, a second internal clock signal QCLK, a third internal clock signal ICLKB, and a fourth internal clock signal QCLKB by dividing the frequency of the clock signal CLK. The frequency division circuit 273 may generate the first internal clock signal ICLK, the second internal clock signal QCLK, the third internal clock signal ICLKB, and the fourth internal clock signal QCLKB, each having a frequency that is ½ of the frequency of the clock signal CLK. The frequency division circuit 273 may generate the first internal clock signal ICLK, the second internal clock signal QCLK, the third internal clock signal ICLKB, and the fourth internal clock signal QCLKB having different phases. The second internal clock signal QCLK may have a phase that is 90° later than the phase of the first internal clock signal ICLK, the third internal clock signal ICLKB may have a phase that is 90° later than the phase of the second internal clock signal QCLK, and the fourth internal clock signal QCLKB may have a phase that is 90° later than the phase of the third internal clock signal ICLKB. The first internal clock signal ICLK and the third internal clock signal ICLKB may be generated to have opposite phases. The second internal clock signal QCLK and the fourth internal clock signal QCLKB may be generated to have opposite phases. The third internal clock signal ICLKB is the inverted signal of the first internal clock signal ICLK. The fourth internal clock signal QCLKB is the inverted signal of the second internal clock signal QCLK.

The read strobe signal generation circuit 275 may generate a read strobe signal RDQS based on the read pulse RP, the third internal clock signal ICLKB, and the fourth internal clock signal QCLKB. The read strobe signal generation circuit 275 may generate the read strobe signal RDQS, based on the third internal clock signal ICLKB and the fourth internal clock signal QCLKB, when the read pulse RP is enabled. The read strobe signal generation circuit 275 may generate the read strobe signal RDQS, based on the read pulse RP being enabled, the third internal clock signal ICLKB, and the fourth internal clock signal QCLKB. The read strobe signal generation circuit 275 is implemented to generate the read strobe signal RDQS based on the third internal clock signal ICLKB and the fourth internal clock signal QCLKB; however, the read strobe signal generation circuit may be implemented to generate the read strobe signal RDQS based on any two internal clock signals, among the first internal clock signal ICLK, the second internal clock signal QCLK, the third internal clock signal ICLKB, and the fourth internal clock signal QCLKB, according to an embodiment.

The data processing circuit 277 may latch the first to eighth bits LCA<1:8> of the latch command address in synchronization with the read strobe signal RDQS based on the logic level of a test mode signal TM after the start of a read operation of a wafer test operation. The data processing circuit 277 may output the first to eighth bits LCA<1:8> of the latch command address, which have been latched after the start of a read operation of a wafer test operation, as the data DATA<1:8> after a read latency interval.

The data processing circuit 277 may latch the data DATA<1:N> based on the logic level of the test mode signal TM after the start of a write operation after a wafer test operation. The data processing circuit 277 may output, as the transfer data TD<1:N>, the data DATA<1:N> that have been latched based on the logic level of the test mode signal TM after the start of a write operation after a wafer test operation.

The data processing circuit 277 may latch the transfer data TD<1:N> based on the logic level of the test mode signal TM after the start of a read operation after a wafer test operation. The data processing circuit 277 may output, as the data DATA<1:N>, the transfer data TD<1:N> that have been latched based on the logic level of the test mode signal TM after the start of a write operation after a wafer test operation.

FIG. 8 is a table for describing the command address that performs a read operation according to an embodiment of the present disclosure.

Logic level combinations of the command address for performing a read operation READ and a read auto-precharge operation READ W AP according to embodiments of the present disclosure are described as follows with reference to FIG. 8.

The command address for performing the read operation READ may correspond to a case in which the first bit CA<1> of the command address that is input in synchronization with a rising edge Rising of the clock signal CLK is at a logic high level H, the second bit CA<2> of the command address that is input in synchronization with the rising edge Rising of the clock signal CLK is at a logic low level L, the third bit CA<3> of the command address that is input in synchronization with the rising edge Rising of the clock signal CLK is at a logic high level H, and the fourth bit CA<4> of the command address that is input in synchronization with the rising edge Rising of the clock signal CLK is at a logic low level L. The read operation READ may be set as an operation that outputs the data DATA<1:N> stored in the plurality of core dies 121-1 to 121-L of the memory device 17.

After the start of the read operation READ, the fifth bit CA<5> of the command address that is input in synchronization with the rising edge Rising of the clock signal CLK may be set as a first bit CID<1> of a chip ID, and the sixth bit CA<6> of the command address that is input in synchronization with the rising edge Rising of the clock signal CLK may be set as a second bit CID<2> of the chip ID. The first and second bits CID<1:2> of the chip ID may be set as a signal that selects the plurality of core dies 121-1 to 121-L. For example, when the first and second bits CID<1:2> of the chip ID are “L, L”, the first core die 121-1, among the plurality of core dies 121-1 to 121-L, may be selected and may perform the read operation READ. When the first and second bits CID<1:2> of the chip ID are “L, H”, the second core die 121-2, among the plurality of core dies 121-1 to 121-L, may be selected and may perform the read operation READ.

After the start of the read operation READ, the seventh bit CA<7> of the command address that is input in synchronization with the rising edge Rising of the clock signal CLK may be set as a first bit BKA<1> of a bank address, the eighth bit CA<8> of the command address that is input in synchronization with the rising edge Rising of the clock signal CLK may be set as a second bit BKA<2> of the bank address, the first bit CA<1> of the command address that is input in synchronization with a falling edge Falling of the clock signal CLK may be set as a third bit BKA<3> of the bank address, and the second bit CA<2> of the command address that is input in synchronization with the falling edge Falling of the clock signal CLK may be set as a fourth bit BKA<4> of the bank address. The first to fourth bits BKA<1:4> of the bank address may be set as a signal that selects a plurality of banks included in each of the plurality of core dies 121-1 to 121-L. For example, when the first to fourth bits BKA<1:4> of the bank address are “L, L, L, L”, the first bank, among the plurality of banks included in each of the plurality of core dies 121-1 to 121-L, may be selected and may perform the read operation READ. When the first to fourth bits BKA<1:4> of the bank address are “L, L, L, H”, the second bank, among the plurality of banks included in each of the plurality of core dies 121-1 to 121-L, may be selected and may perform the read operation READ.

After the start of the read operation READ, the third bit CA<3> of the command address that is input in synchronization with the falling edge Falling of the clock signal CLK may be set as a first bit COLA<1> of a column address, the fourth bit CA<4> of the command address that is input in synchronization with the falling edge Falling of the clock signal CLK may be set as a second bit COLA<2> of the column address, the fifth bit CA<5> of the command address that is input in synchronization with the falling edge Falling of the clock signal CLK may be set as a third bit COLA<3> of the column address, the sixth bit CA<6> of the command address that is input in synchronization with the falling edge Falling of the clock signal CLK is set as a fourth bit COLA<4> of the column address, the seventh bit CA<7> of the command address that is input in synchronization with the falling edge Falling of the clock signal CLK may be set as a fifth bit COLA<5> of the column address, and the eighth bit CA<8> of the command address that is input in synchronization with the falling edge Falling of the clock signal CLK may be set as a sixth bit COLA<6> of the column address. The first to sixth bits COLA<1:6> of the column address may be set as a signal that selects a column path included in each of a plurality of banks. For example, when the first to sixth bits COLA<1:6> of the column address are “L, L, L, L, L, L”, the first column path, among a plurality of column paths included in each of the plurality of banks, may be selected and may perform the read operation READ. When the first to sixth bits COLA<1:6> of the column address are “L, L, L, L, L, H”, the second column path, among the plurality of column paths included in each of the plurality of banks, may be selected and may perform the read operation READ.

The command address for performing the read auto-precharge operation READ W AP may correspond to a case in which the first bit CA<1> of the command address that is input in synchronization with a rising edge Rising of the clock signal CLK is at a logic high level H, the second bit CA<2> of the command address that is input in synchronization with the rising edge Rising of the clock signal CLK is at a logic low level L, the third bit CA<3> of the command address that is input in synchronization with the rising edge Rising of the clock signal CLK is at a logic high level H, and the fourth bit CA<4> of the command address that is input in synchronization with the rising edge Rising of the clock signal CLK is at a logic high level H. The read auto-precharge operation READ W AP may be set as an operation that sequentially performs a read operation and a precharge operation that outputs the data DATA<1:N> stored in the plurality of core dies 121-1 to 121-L of the memory device 17.

The first to eighth bits CA<1:8> of the command address that are input in synchronization with the rising edge Rising and falling edge Falling of the clock signal CLK after the start of the read auto-precharge operation READ W AP may be the same as the first to eighth bits CA<1:8> of the command address that are input in synchronization with the rising edge Rising and falling edge Falling of the clock signal CLK after the start of the read operation READ, and thus, a detailed description thereof is omitted.

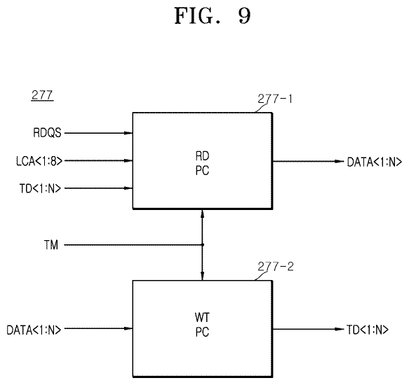

FIG. 9 is a block diagram illustrating a construction of the data processing circuit 277 according to an embodiment of the present disclosure. The data processing circuit 277 may include a read processing circuit (RD PC) 277-1 and a write processing circuit (WT PC) 277-2.

The read processing circuit 277-1 may latch the first to eighth bits LCA<1:8> of the latch command address in synchronization with the read strobe signal RDQS when the test mode signal TM is enabled to a logic high level after the start of a read operation of a wafer test operation. The read processing circuit 277-1 may output the first to eighth bits LCA<1:8> of the latch command address, which have been latched when the test mode signal TM is enabled to a logic high level after the start of a read operation of a wafer test operation, as the first to eighth bits DATA<1:8> of the data after a read latency interval. The first to eighth bits LCA<1:8> of the latch command address that are input to the read processing circuit 277-1 may be generated from the first to eighth bits CA<1:8> of the command address that are input in synchronization with the rising edge Rising and falling edge Falling of the clock signal CLK, as described with reference to FIG. 8.

The read processing circuit 277-1 may latch the first to N-th bits TD<1:N> of the transfer data when the test mode signal TM is disabled to a logic low level after the start of a read operation after a wafer test operation. The read processing circuit 277-1 may output the first to N-th bits TD<1:N> of the transfer data, which have been latched when the test mode signal TM is disabled to a logic low level after the start of a read operation after a wafer test operation, as the first to N-th bits DATA<1:N> of the data.

The write processing circuit 277-2 may latch the first to N-th bits DATA<1:N> of the data when the test mode signal TM is disabled to a logic low level after the start of a write operation of a wafer test operation. The write processing circuit 277-2 may output the first to N-th bits DATA<1:N> of the data, which have been latched when the test mode signal TM is disabled to a logic low level after the start of a write operation of a wafer test operation, as the first to N-th bits TD<1:N> of the transfer data.

The write processing circuit 277-2 may latch the first to N-th bits DATA<1:N> of the data when the test mode signal TM is disabled to a logic low level after the start of a write operation after a wafer test operation. The write processing circuit 277-2 may output the first to N-th bits DATA<1:N> of the data, which have been latched when the test mode signal TM is disabled to a logic low level after the start of a write operation after a wafer test operation, as the first to N-th bits TD<1:N>of the transfer data.

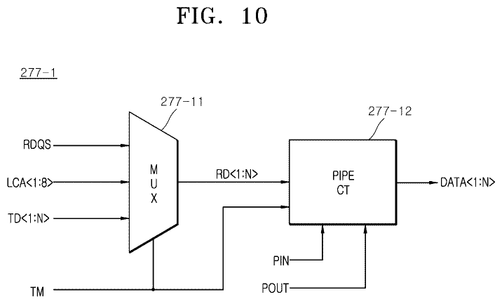

FIG. 10 is a block diagram illustrating a construction of the read processing circuit 277-1 according to an embodiment of the present disclosure. The read processing circuit 277-1 may include a multiplexer (MUX) 277-11 and a pipe circuit (PIPE CT) 277-12.

The multiplexer 277-11 may output the read strobe signal RDQS as an N-th bit RD<N> of read data when the test mode signal TM is enabled to a logic high level. The multiplexer 277-11 may output the first to eighth bits LCA<1:8> of the latch command address as first to eighth bits RD<1:8> of the read data when the test mode signal TM is enabled to a logic high level.

The multiplexer 277-11 may output the first to N-th bits TD<1:N> of the transfer data as the first to N-th bits RD<1:N> of the read data when the test mode signal TM is disabled to a logic low level.

The pipe circuit 277-12 may latch the first to eighth bits RD<1:8> of the read data in synchronization with the N-th bit RD<N>of the read data when the test mode signal TM is enabled to a logic high level. The pipe circuit 277-12 may output the first to eighth bits RD<1:8> of the read data, which have been latched when the test mode signal TM is enabled to a logic high level and an output control signal POUT is enabled to a logic high level after a read latency interval, as the first to eighth bits DATA<1:8> of the data.

The pipe circuit 277-12 may latch the first to N-th bits RD<1:N> of the read data in synchronization with an input control signal PIN when the test mode signal TM is disabled to a logic low level. The pipe circuit 277-12 may output the first to N-th bits RD<1:N> of the read data, which have been latched when the test mode signal TM is disabled to a logic low level and the output control signal POUT is enabled to a logic high level after a read latency interval, as the first to N-th bits DATA<1:N> of the data.

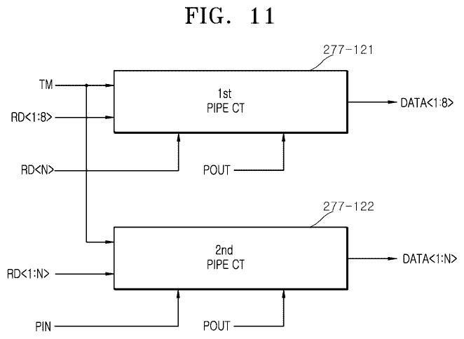

FIG. 11 is a block diagram illustrating a construction of the pipe circuit 277-12 according to an embodiment of the present disclosure. The pipe circuit 277-12 may include a first pipe circuit (1st PIPE CT) 277-121 and a second pipe circuit (2nd PIPE CT) 277-122.

The first pipe circuit 277-121 may latch the first to eighth bits RD<1:8> of the read data in synchronization with the N-th bit RD<N> of the read data when the test mode signal TM is enabled to a logic high level. The first pipe circuit 277-121 may output the first to eighth bits RD<1:8> of the read data, which have been latched when the test mode signal TM is enabled to a logic high level and the output control signal POUT is enabled to a logic high level after a read latency interval, as the first to eighth bits DATA<1:8> of the data.

The second pipe circuit 277-122 may latch the first to N-th bits RD<1:N> of the read data in synchronization with the input control signal PIN when the test mode signal TM is disabled to a logic low level. The second pipe circuit 277-122 may output the first to N-th bits RD<1:N> of the read data, which have been latched when the test mode signal TM is disabled to a logic low level and the output control signal POUT is enabled to a logic high level after a read latency interval, as the first to N-th bits DATA<1:N> of the data.

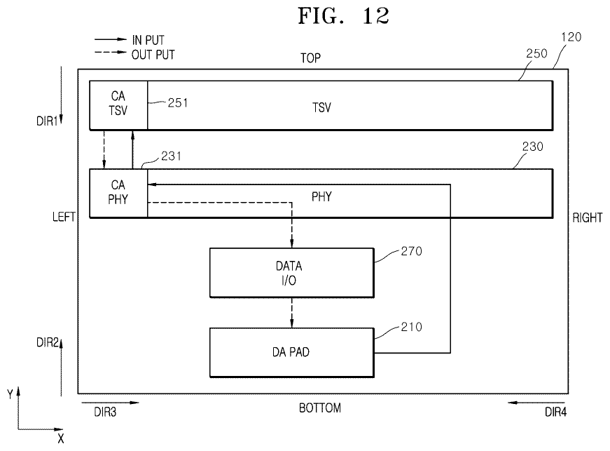

FIG. 12 is a diagram for describing an operation of detecting a fault in a signal transmission path along which the command address is transmitted after the start of a wafer test operation in the base die 120 according to an embodiment of the present disclosure.

Based on the X-Y plane, the TSV region 250 may be disposed on the top side TOP of the base die 120 when using the Y-axis as reference.

The physical region 230 may be disposed in a first direction DIR1 from the TSV region 250. The first direction DIR1 may be set as a −Y direction.

The data input and output circuit 270 may be disposed in the first direction DIR1 from the physical region 230.

The DA pad region 210 may be disposed in the first direction DIR1 from the data input and output circuit 270.

According to an embodiment, in the base die 120, the TSV region 250 may be implemented to be disposed on the bottom side BOTTOM when using the Y-axis as reference. If the TSV region 250 is disposed on the bottom side BOTTOM in the Y axis in the base die 120, the physical region 230, the data input and output circuit 270, and the DA pad region 210 may be sequentially disposed in a second direction DIR2 from the TSV region 250. The second direction DIR2 may be set as a +Y direction.

According to an embodiment, in the base die 120, the TSV region 250 may be implemented to be disposed on the left side LEFT when using the X axis as reference. If the TSV region 250 is disposed on the left side LEFT in the X axis in the base die 120, the physical region 230, the data input and output circuit 270, and the DA pad region 210 may be sequentially disposed in a third direction DIR3 from the TSV region 250. The third direction DIR3 may be set as a +X direction.

According to an embodiment, in the base die 120, the TSV region 250 may be implemented to be disposed on the right side RIGHT when using the X axis as reference. If the TSV region 250 is disposed on the right side RIGHT in the X axis in the base die 120, the physical region 230, the data input and output circuit 270, and the DA pad region 210 may be sequentially disposed in a fourth direction DIR4 from the TSV region 250. The fourth direction DIR4 may be set as a-X direction.

Locations at which the DA pad region 210, the physical region 230, the TSV region 250, and the data input and output circuit 270 are disposed may vary according to an embodiment.

The DA pad region 210 may receive (INPUT) the command address CA<1:8> from the processor 19 of FIG. 1 through a wire of the interposer 15 of FIG. 1 and may output the command address CA<1:8> to the command address physical region 231 after the start of a wafer test operation.

The command address physical region 231 may generate the internal command address ICA<1:8> by receiving the command address CA<1:8> after the start of the wafer test operation. The command address physical region 231 may output the internal command address ICA<1:8> to the command address TSV region 251.

The command address TSV region 251 may apply the internal command address ICA<1:8> to the command address TSV (T251 in FIG. 5) by receiving the internal command address ICA<1:8>after the start of the wafer test operation. The command address TSV region 251 may latch the internal command address ICA<1:8> after the start of the wafer test operation. The command address TSV region 251 may generate the latch command address LCA<1:8> based on the logic level of the command address TSV (T251 in FIG. 5) after the start of the wafer test operation. The command address TSV region 251 may output (OUTPUT) the latch command address LCA<1:8> to the data input and output circuit 270 after the start of the wafer test operation.

The data input and output circuit 270 may generate the data DATA<1:8> based on the latch command address LCA<1:8> after the start of a read operation of the wafer test operation. The data input and output circuit 270 may output the data DATA<1:8> to the DA pad region 210.

When the data DATA<1:8> output from the DA pad region 210 through a wire of the interposer 15 are the same as the command address CA<1:8> after the start of the wafer test operation, the processor 19 may detect that there is no fault in the first signal transmission path along which the command address is transmitted. When the data DATA<1:8> output from the DA pad region 210 through a wire of the interposer 15 are different from the command address CA<1:8> after the start of the wafer test operation, the processor 19 may detect that a fault has occurred in the first signal transmission path along which the command address is transmitted.

The processor 19 may control the base die 120 that outputs the command address CA<1:8> to the core dies 121-1 to 121-L by excluding a signal transmission path having a fault, among signal transmission paths to which the command address is applied.

An operation of detecting a fault in one first signal transmission path after the start of a wafer test operation according to an embodiment of the present disclosure has been described with reference to FIG. 12, for convenience of description. However, an embodiment of the present disclosure may be implemented to sequentially detect faults in a plurality of first signal transmission paths.

An operation of detecting a fault in the second signal transmission path after the start of a wafer test operation in the base die 120 according to an embodiment of the present disclosure includes outputting the data DATA<1:N> through the data physical region 233, the data TSV region 253, and the data input and output circuit 270 and is similar to the operation of detecting a fault in the first signal transmission path, and a detailed description thereof is omitted.

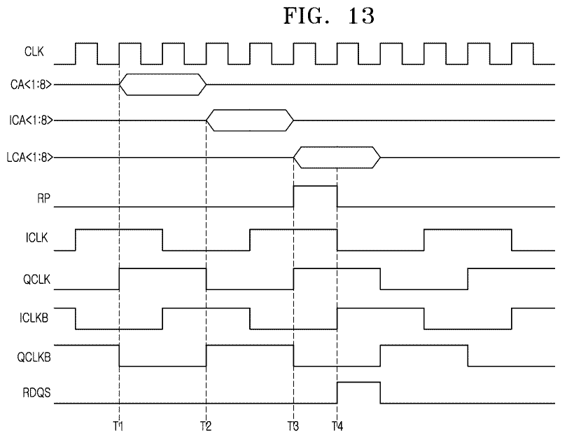

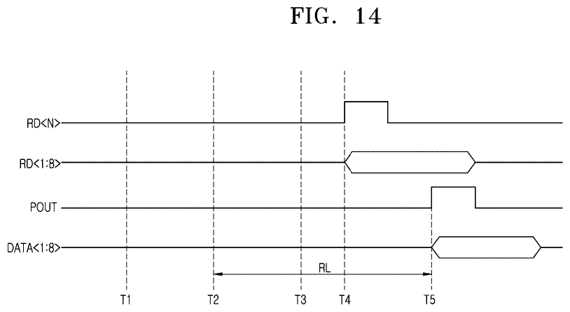

FIGS. 13 and 14 are timing diagrams for describing a wafer test operation in the base die 120 according to an embodiment of the present disclosure. The wafer test operation in the base die is described as follows with reference to FIGS. 13 and 14.

At time T1, the first pad 211 of the DA pad region 210 may receive and output the command address CA<1:8> after the start of a wafer test operation.

At time T2, the command address physical region 231 of the physical region 230 may generate the internal command address ICA<1:8> by receiving the command address CA<1:8> that are input at time T1.

At time T3, the command address TSV region 251 of the TSV region 250 may apply the internal command address ICA<1:8>generated at time T2 to the command address TSV T251 and may latch the internal command address ICA<1:8>. The command address TSV region 251 may generate the latch command address LCA<1:8>based on the logic level of the command address TSV T251.

The read pulse generation circuit 271 of the data input and output circuit 270 may generate the read pulse RP at a logic high level when the first to fourth bits LCA<1:4> of the latch command address that are input in synchronization with the clock signal CLK have a logic level combination for performing a read operation.

The frequency division circuit 273 of the data input and output circuit 270 may generate the first internal clock signal ICLK, the second internal clock signal QCLK, the third internal clock signal ICLKB, and the fourth internal clock signal QCLKB by dividing the frequency of the clock signal CLK. The frequency division circuit 273 may generate the first internal clock signal ICLK, the second internal clock signal QCLK, the third internal clock signal ICLKB, and the fourth internal clock signal QCLKB, each having a frequency that is ½ of the frequency of the clock signal CLK. The frequency division circuit 273 may generate the first internal clock signal ICLK, the second internal clock signal QCLK, the third internal clock signal ICLKB, and the fourth internal clock signal QCLKB having different phases.

At time T4, the read strobe signal generation circuit 275 of the data input and output circuit 270 may generate the read strobe signal RDQS at a logic high level based on the third internal clock signal ICLKB and the fourth internal clock signal QCLKB, when the read pulse RP is enabled at time T3.

The multiplexer 277-11 of the read processing circuit 277-1 outputs the read strobe signal RDQS as the N-th bit RD<N> of the read data when the test mode signal TM is enabled to a logic high level. The multiplexer 277-11 outputs the first to eighth bits LCA<1:8> of the latch command address as the first to eighth bits RD<1:8> of the read data when the test mode signal TM is enabled to a logic high level.

The pipe circuit 277-12 of the read processing circuit 277-1 may latch the first to eighth bits RD<1:8> of the read data in synchronization with the N-th bit RD<N> of the read data when the test mode signal TM is enabled to a logic high level.

At time T5, the pipe circuit 277-12 of the read processing circuit 277-1 may output the first to eighth bits RD<1:8> of the read data, which have been latched when the test mode signal TM is enabled to a logic high level and the output control signal POUT is enabled to a logic high level after a read latency interval RL, as the first to eighth bits DATA<1:8> of the data. The read latency interval may be set as a time from time T2 to time T5, that is, a time at which the internal command address ICA<1:8> for a read operation is input. The read latency interval may be variously set according to an embodiment.

The base die 120 of the memory system 1 according to an embodiment of the present disclosure can detect a fault in a signal transmission path by applying the command address to the signal transmission path after the start of a wafer test operation and outputting the command address through another signal transmission path after the start of a read operation. The memory system 1 can prevent an operation error in transmitting a signal to the plurality of core dies by excluding a signal transmission path having a fault. The memory system 1 can improve the yield by testing a signal transmission path for dies before the dies included in the stack memory device 17 are stacked and screening a die having a fault.

What is claimed is:

1. A memory system comprising:
a base die configured to control operations of a plurality of core dies;
a processor connected to the base die through an interposer,
wherein the base die is further configured to:
apply a command address to a command address through silicon via (TSV) by receiving the command address through a first signal transmission path after a start of a wafer test operation;
output a latch command address generated based on a logic level of the command address TSV as data through a second signal transmission path after a start of a read operation; and
detect a fault in the first signal transmission path based on a logic level of the data.

2. The memory system of claim 1, wherein the plurality of core dies is stacked over the base die after the wafer test operation is terminated.

3. The memory system of claim 1,
wherein the first signal transmission path is set as a unilateral signal transmission path along which the command address is received, and
wherein the second signal transmission path is set as a bidirectional signal transmission path along which the data are received and output.

4. The memory system of claim 1, wherein the base die comprises:
a data (DA) pad region configured to receive the command address and configured to input and output the data;
a physical region configured to generate an internal command address by receiving the command address;
a TSV region configured to apply the internal command address to the command address TSV and configured to generate the latch command address based on a logic level of the command address TSV; and
a data input and output circuit configured to generate the data based on the latch command address after the start of the read operation and configured to output the data to the DA pad region.

5. The memory system of claim 4, wherein the TSV region comprises:
the command address TSV configured to receive the internal command address; and
a command address latch circuit configured to latch the internal command address applied to the command address TSV and configured to output the latch command address based on a logic level of the command address TSV.

6. The memory system of claim 4, wherein the data input and output circuit comprises:
a read pulse generation circuit configured to generate a read pulse when the latch command address that is input in synchronization with a clock signal has a logic level combination for performing the read operation;
a frequency division circuit configured to generate the first to fourth internal clock signals by dividing a frequency of the clock signal;
a read strobe signal generation circuit configured to generate a read strobe signal based on the third and fourth internal clock signals when the read pulse is enabled; and
a data processing circuit configured to latch the latch command address in synchronization with the read strobe signal and configured to output the latch command address that is latched as the data after a read latency interval.

7. The memory system of claim 6, wherein the data processing circuit comprises a pipe circuit configured to latch remaining bits of read data generated from the latch command address in synchronization with any one bit of read data generated from the read strobe signal and configured to output the remaining bits of the read data, which have been latched, after the read latency interval.

8. The memory system of claim 4,
wherein the TSV region is disposed on one side of the base die,
wherein the physical region is disposed in a first direction from the TSV region,
wherein the data input and output circuit is disposed in the first direction from the physical region, and
wherein the DA pad region is disposed in the first direction from the data input and output circuit.

9. The memory system of claim 8, wherein the first direction is a direction from the one side of the base die to a side that is opposite to the one side of the base die.

10. A memory system comprising:
a base die configured to control operations of a plurality of core dies;
a processor connected to the base die through an interposer,
wherein the base die is further configured to:
apply a command address to a command address through silicon via (TSV) by receiving the command address through a first signal transmission path after a start of a wafer test operation;
output a latch command address generated based on a logic level of the command address TSV as data through a second signal transmission path;
apply the data to a data TSV by receiving the data through the second signal transmission path;
output transfer data generated based on a logic level of the data TSV as the data through the second signal transmission path; and
detect a fault in the first signal transmission path and the second signal transmission path based on a logic level of the data.

11. The memory system of claim 10, wherein the plurality of core dies is stacked over the base die after the wafer test operation is terminated.

12. The memory system of claim 10,
wherein the first signal transmission path is set as a unilateral signal transmission path along which the command address is received, and
wherein the second signal transmission path is set as a bidirectional signal transmission path along which the data are received and output.

13. The memory system of claim 10, wherein the base die comprises:
a data (DA) pad region configured to receive the command address and configured to input and output the data;
a physical region configured to generate an internal command address by receiving the command address, configured to generate internal data by receiving the transfer data generated from the data, and configured to generate the transfer data from the internal data;
a TSV region configured to apply the internal command address to the command address TSV, configured to generate the latch command address based on a logic level of the command address TSV, and configured to apply the internal data to the data TSV; and
a data input and output circuit configured to generate the data based on the latch command address after a start of a read operation, configured to output the data to the DA pad region or to generate the data based on the transfer data generated from the internal data, and configured to output the data to the DA pad region.

14. The memory system of claim 13, wherein the TSV region comprises:
the command address TSV configured to receive the internal command address; and
a command address latch circuit configured to latch the internal command address applied to the command address TSV and configured to output the latch command address based on a logic level of the command address TSV.

15. The memory system of claim 13, wherein the TSV region comprises:
a data TSV configured to receive the internal data; and
a data latch circuit configured to latch the internal data applied to the data TSV and configured to generate the internal data based on a logic level of the data TSV.

16. The memory system of claim 13, wherein the data input and output circuit comprises:
a read pulse generation circuit configured to generate a read pulse when the latch command address that is input in synchronization with a clock signal has a logic level combination for performing the read operation;
a frequency division circuit configured to generate the first to fourth internal clock signals by dividing a frequency of the clock signal;
a read strobe signal generation circuit configured to generate a read strobe signal based on the third and fourth internal clock signals when the read pulse is enabled; and
a data processing circuit configured to latch the latch command address in synchronization with the read strobe signal based on a test mode signal, configured to output the latch command address that is latched as the data after a read latency interval or to generate the transfer data by latching the data after a start of a write operation based on the test mode signal, and configured to generate the data by latching the transfer data after the start of the read operation.

17. The memory system of claim 16, wherein the data processing circuit comprises:
a read processing circuit configured to latch the latch command address in synchronization with the read strobe signal when the test mode signal is enabled, configured to output the latch command address that is latched as the data after the read latency interval, and configured to generate the data by latching the transfer data when the test mode signal is disabled; and
a write processing circuit configured to generate the transfer data by latching the data when the test mode signal is disabled.

18. The memory system of claim 17, wherein the read processing circuit comprises:
a multiplexer configured to output the read strobe signal as any one bit of read data when the test mode signal is enabled, configured to output the latch command address as remaining bits of the read data, and configured to output the transfer data as the read data when the test mode signal is disabled; and
a pipe circuit configured to latch the remaining bits of the read data in synchronization with any one bit of the read data when the test mode signal is enabled, configured to output the remaining bits of the read data as the data when an output control signal is enabled after the read latency interval, configured to latch the read data when the test mode signal is disabled and an input control signal is enabled, and configured to output the read data as the data when the output control signal is enabled.

19. A memory system comprising:
a base die configured to control operations of a plurality of core dies;
a processor connected to the base die through an interposer,
wherein the base die is further configured to:
sequentially apply a command address to a plurality of command address through silicon vias (TSVs) by receiving the command address through a plurality of first signal transmission paths after a start of a wafer test operation;
sequentially output a plurality of latch command addresses generated based on logic levels of the plurality of command address TSVs as data through a second signal transmission path after a start of a read operation; and
detect a fault in the plurality of first signal transmission paths based on a logic level of the data.

20. The memory system of claim 19, wherein the plurality of core dies is vertically stacked over the base die through a plurality of command address TSVs and a data TSV after the wafer test operation is terminated.

21. The memory system of claim 19, wherein the base die outputs the command address to the plurality of core dies by excluding a first signal transmission path having a fault, among the plurality of first signal transmission paths.

22. The memory system of claim 19, further comprising:
an interposer stacked over a substrate; and
the processor stacked over the interposer and connected to the base die through a wire formed within the interposer,
wherein the processor is configured to control the base die configured to output the command address to the plurality of core dies by excluding a first signal transmission path having a fault, among the plurality of first signal transmission paths.

23. A base die comprising:
a data (DA) pad region configured to receive a command address and configured to input and output data;
a physical region configured to generate an internal command address by receiving the command address;
a through silicon via (TSV) region configured to apply the internal command address to a command address TSV and configured to generate a latch command address based on a logic level of the command address TSV; and
a data input and output circuit configured to generate the data based on the latch command address after a start of a read operation of a wafer test operation and configured to output the data to the DA pad region,
wherein the base die detects a fault in the physical region and the TSV region based on a logic level of the data.

24. The base die of claim 23, wherein the physical region and the TSV region form a unilateral signal transmission path that receives the command address.

25. The base die of claim 23, wherein the TSV region comprises:
the command address TSV configured to receive the internal command address; and
a command address latch circuit configured to latch the internal command address applied to the command address TSV and configured to output the latch command address based on a logic level of the command address TSV.

26. The base die of claim 23, wherein the data input and output circuit comprises:
a read pulse generation circuit configured to generate a read pulse when the latch command address that is input in synchronization with a clock signal has a logic level combination for performing the read operation;
a frequency division circuit configured to generate first to fourth internal clock signals by dividing a frequency of the clock signal;
a read strobe signal generation circuit configured to generate a read strobe signal based on third and fourth internal clock signals when the read pulse is enabled; and
a data processing circuit configured to latch the latch command address in synchronization with the read strobe signal and configured to output the latch command address that is latched as the data after a read latency interval.
